(19) United States
(12) Patent Application Publication
(10) Pub. No.: US 2017/0069870 A1
(43) Pub. Date: Mar. 9, 2017

(54) DISPLAY PANEL, METHOD FOR PACKAGING THE SAME, AND DISPLAY DEVICE

(71) Applicant: BOE TECHNOLOGY GROUP CO., LTD., Beijing (CN)

(72) Inventors: Dan WANG, Beijing (CN); Libin LIU, Beijing (CN)

(73) Assignee: BOE TECHNOLOGY GROUP CO., LTD., Beijing (CN)

(21) Appl. No.: 14/914,450

(22) PCT Filed: Aug. 10, 2015
(86) PCT No.: PCT/CN2015/086447

§ 371 Date: Feb. 25, 2016

(30) Foreign Application Priority Data
Apr. 21, 2015 (CN) 201510190980.0

(51) Int. Cl. H01L 51/52; H01L 51/56; H01L 27/32

(52) U.S. Cl. CPC H01L 51/529; H01L 27/3244; H01L 51/5246; H01L 27/322; H01L 51/56; H01L 2251/308

(57) ABSTRACT

The present application provides a display panel, a method for packaging the display panel and a display device. The present application provides a display panel including: a first substrate, a second substrate which is oppositely arranged with respect to the first substrate to form a cell. A sealant layer is arranged between the first substrate and the second substrate, and the first substrate and the second substrate are adhered together by the sealant layer. A first heat conducting pattern is arranged on the first substrate at a position corresponding to a position of the sealant layer, and the first heat conducting pattern is in contact with the sealant layer. The first heat conducting pattern is capable of conducting heat produced by laser during the process of heating the sealant by the laser to form a sealant layer.

### CROSS REFERENCE OF RELATED APPLICATION

The present application claims a priority of Chinese patent application No. 201510190980.0 filed on Apr. 21, 2015, the disclosure of which is incorporated herein by reference in its entirety.

### TECHNICAL FIELD

The present application relates to a technical field of displaying, and more particular to a display panel, a method for manufacturing the display panel and a display device.

### BACKGROUND

In recent years, it is focused more on manufacturing a new panel display by organic light-emitting diode (OLED) devices. The OLED device has advantages such as self luminescent, high brightness, high definition, wide view angel, fast response, low power consumption and capability of being flexible, and thus the OLED display may be a next generation display device for taking the place of the liquid crystal display (LCD) display. However, an organic layer which is sensitive to moisture and oxygen is arranged in the OLED device, and thus a service life of the OLED device is significantly reduced. Conventionally, for solving the above problem, an OLED array substrate is packaged by a packaging substrate to isolate the organic layer from outside air.

In the related art, the OLED array substrate and the packaging substrate are packaged mainly by glass sealant in a small or a medium sized OLED device. In such a packaging method, the OLED array substrate and/or the packaging substrate is coated with the glass sealant, and then the glass sealant is heated and melted by moving laser beam in a nitrogen environment. As a result, a sealed encapsulation is formed between the two substrates by the melted glass sealant, and thus an airtight package is implemented.

However, it is possible that the glass sealant on some areas of the substrates is not heated sufficiently by the laser beam, and thus is not melted, so that the adhesion of the substrates might be deteriorated. Furthermore, the glass sealant is in direction contact with the substrates after packaging, and therefore the adhesion of the substrates by the glass sealant is weaker than the adhesion of the substrates by another packaging adhesive (for example, UV adhesive) due to a stress caused by mismatching of thermal expansion coefficients of the glass sealant and the substrates. As a result, in the related art, the adhesion of the two substrates by the glass sealant is weak, and thus the two substrates might be mechanically separated from each other after being packaged.

### SUMMARY

One technical problem to be solved by the present application is to provide a display panel, a method for packaging the display panel, and a display device, which can enhance the adhesion of the substrates by the sealant and improve the mechanical strength of the packaging, and thus prolong the service life of the display device.

In the present application, it is provided the following technical solutions for solving the above technical problem.

In one aspect, the present application provides a display panel, including: a first substrate; a second substrate which is oppositely arranged with respect to the first substrate to form a cell; a sealant layer arranged between the first substrate and the second substrate; wherein the first substrate and the second substrate are adhered together by the sealant layer; and a first heat conducting pattern arranged on the first substrate at a position corresponding to a position of the sealant layer, and the first heat conducting pattern being in contact with the sealant layer.

Further, the first heat conducting pattern is a full pattern without any hollow area.

Further, an orthographic projection of the sealant layer on the first substrate entirely falls into an area corresponding to the first heat conducting pattern.

Further, the first heat conducting pattern includes a plurality of hollow areas defined therein.

Further, each of the hollow areas is in a shape of square, rectangular, triangle or circle.

Further, the display panel further includes a second heat conducting pattern arranged on the second substrate at a position corresponding to the position of the sealant layer, and the second heat conducting pattern being in contact with the sealant layer.

Further, the second heat conducting pattern is a full pattern without any hollow area; or, the second heat conducting pattern includes a plurality of hollow areas defined therein.

Further, when the second heat conducting patter is the full pattern without any hollow area, an orthographic projection of the sealant layer on the second substrate entirely falls into an area corresponding to the second heat conducting pattern.

Further, both the first heat conducting pattern and the second heat conducting pattern are made of inorganic electricity conductive material.

Further, the inorganic electricity conductive material is indium tin oxide (ITO), indium zinc oxide (IZO) or indium gallium zinc oxide (IGZO).

Further, the first substrate is an array substrate, and the second substrate is a color filter substrate; or, the first substrate is the color filter substrate, and the second substrate is the array substrate.

Further, the second substrate is an organic light emitting diode (OLED) array substrate, and the first substrate is a packaging substrate.

Further, the first heat conducting pattern is electrically connected to a cathode layer on the OLED array substrate via two or more connecting points, respectively.

Further, the sealant layer is made of glass sealant.

The present application further provides a display device including the above display panel.

The present application further provides a method for packaging the display panel, including steps of: forming the first heat conducting pattern on the first substrate at a position where the sealant is to be adhered; coating the sealant on the first substrate with the sealant in contact with the first heat conducting pattern; and irradiating the sealant by laser to heat the sealant to melt, and adhering the first substrate and the second substrate by the melted sealant; wherein the first heat conducting pattern is capable of conducting heat produced by the laser during the process of irradiating the sealant.

Further, before the step of coating the sealant on the first substrate, the method further includes: forming a second heat conducting pattern on the second substrate at a position where the sealant is to be adhered; wherein the sealant coated on the first substrate is in contact with the second heat conducting pattern; during the process of irradiating the sealant by laser to heat the sealant to melt and adhering the first substrate and the second substrate by the melted sealant, the second heat conducting pattern is capable of conducting heat produced by the laser.

In the embodiments of the present application, the following technical effects may be obtained.

In the above solutions, the first heat conducting pattern is arranged on the first substrate at a position corresponding to a position of the sealant layer, and the first heat conducting pattern is in contact with the sealant layer. The first heat conducting pattern is capable of conducting heat produced by the laser during the process of heating the sealant by the laser to form the sealant layer for adhering the first substrate and the second substrate, so that the heat may spread during the process of heating the sealant by the laser, and thus the sealant is heated sufficiently to be melted. As a result, the adhesion of the first substrate and the second substrate by the sealant is enhanced. Furthermore, at least a portion of the sealant is not in direct contact with the first substrate, so that it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

### BRIEF DESCRIPTION OF THE DRAWINGS

FIG. 1 is a schematic view of an OLED display device in the related art;

FIG. 2 is a schematic view of an OLED display device according to one embodiment of the present application;

FIG. 3 is a schematic view of an OLED display device according to another embodiment of the present application;

FIG. 4 is a schematic view showing a heat conducting pattern on a packaging substrate according to one embodiment of the present application; and

FIG. 5 is a schematic view showing hollow areas arranged on the heat conducting pattern according to one embodiment of the present application.

### REFERENCE SIGNS

1: Packaging Substrate; 2: Active Layer;
3: Source-Drain Electrode Layer; 4: Pixel Light-Emitting Area;
5: Glass Sealant; 6: Second Insulation Layer;
7 First Insulation Layer; 8: Inorganic Buffer Layer;
9: Base Substrate; 10, 12: Heat Conducting Pattern;
11: Pixel Electrode; 13: Cathode Layer;
14: Hollow Area.

### DETAILED DESCRIPTION

Hereinafter, it will be discussed in details associated with drawings and embodiments for further clarifying technical problems, technical solutions and advantages of the embodiments of the present application.

In the embodiments of the present application, it is provided a display panel, a method for packaging the display panel and a display device for solving the problem that the adhesion of the two substrates by the glass sealant is weak and thus the two substrates might be mechanically separated from each other after being packaged in the related art. As a result, the adhesion of the substrates by the sealant is enhanced and the mechanical strength of the packaging is improved, and thus the service life of the display device is prolonged.

### Embodiment 1

In this embodiment, it is provided a display panel including: a first substrate, a second substrate which is oppositely arranged with respect to the first substrate to form a cell, and a sealant layer arranged between the first substrate and the second substrate. The first substrate and the second substrate are adhered together by the sealant layer. A first heat conducting pattern is arranged on the first substrate at a position corresponding to a position of the sealant layer, and the first heat conducting pattern is in contact with the sealant layer. The first heat conducting pattern is capable of conducting heat produced by the laser during the process of heating the sealant by the laser to form the sealant layer.

In this embodiment, the first heat conducting pattern is arranged on the first substrate and at a position corresponding to the position of the sealant layer, and the first heat conducting pattern is in contact with the sealant layer. The first heat conducting pattern is capable of conducting heat produced by the laser during the process of heating the sealant by the laser to form the sealant layer for adhering the first substrate and the second substrate, so that the heat may spread during the process of heating the sealant by the laser, and thus the sealant is heated sufficiently to be melted. As a result, the adhesion of the first substrate and the second substrate by the sealant is enhanced. Furthermore, at least a portion of the sealant is not in direct contact with the first substrate, so that it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

Furthermore, the first heat conducting pattern may be a full pattern without any hollow area. In one embodiment, an orthographic projection of the sealant layer on the first substrate entirely falls into an area corresponding to the first heat conducting pattern, i.e. the first heat conducting pattern is arranged on the first substrate at each position corresponding to the position of the sealant layer, and thus the sealant is not in direct contact with the first substrate in its entirety. As a result, it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

Furthermore, a plurality of hollow areas may be arranged in the first heat conducting pattern. Each of the hollow areas is in a shape of a square, a rectangular, a triangle or a circle. The presence of hollow areas in the first heat conducting pattern can increase contact area between the sealant layer and the substrate, and release the stress better upon adhering the substrates by the sealant layer, so that the adhesion of the substrates is further enhanced, and thus the mechanical strength of the packaging is improved.

Furthermore, a second heat conducting pattern is arranged on the second substrate at a position corresponding to a position of the sealant layer, and the second heat conducting pattern is in contact with the sealant layer. The second heat conducting pattern is capable of conducting heat produced by the laser during the process of heating the sealant by the laser to form the sealant layer, so that the heat may spread to each area during the process of heating the sealant by the laser, and thus the sealant in each area is heated sufficiently to be melted. As a result, the adhesion of the first substrate and the second substrate by the sealant is enhanced. Furthermore, at least a portion of the sealant is not in direct contact with the second substrate, so that it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

Furthermore, the second heat conducting pattern may be a full pattern without any hollow area. In one embodiment, an orthographic projection of the sealant layer on the second substrate entirely falls into an area corresponding to the second heat conducting pattern. In other words, the second heat conducting pattern is arranged on the second substrate at each position corresponding to the position of the sealant layer, and thus the sealant is not in direct contact with the second substrate in its entirety. As a result, it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

Furthermore, a plurality of hollow areas may be arranged in the second heat conducting pattern. Each of the hollow areas is in a shape of a square, a rectangular, a triangle or a circle. The presence of hollow areas in the second heat conducting pattern can increase contact area between the sealant layer and the substrate, and release the stress better upon adhering the substrates by the sealant layer, so that the adhesion of the substrates is further enhanced, and thus the mechanical strength of the packaging is improved.

Furthermore, both the first heat conducting pattern and the second heat conducting pattern are made of inorganic electricity conductive material, so that the heat conducting capabilities of the first heat conducting pattern and the second heat conducting pattern are improved.

In this embodiment, the display panel may be a LCD panel. The first substrate is an array substrate, and the second substrate is a color filter substrate; or, the first substrate is the color filter substrate, and the second substrate is the array substrate.

In this embodiment, the display panel may be an OLED display panel, wherein the second substrate is an OLED array substrate, and the first substrate is a packaging substrate.

Furthermore, when the display panel is an OLED display panel and the first heat conducting pattern is made of the inorganic electricity conductive material, the first heat conducting pattern is electrically connected to a cathode layer on the OLED array substrate via two or more connecting points, respectively. As a result, the first heat conducting pattern may be in parallel connection with the cathode layer on the OLED array substrate, and thus the resistance and the voltage drop of the cathode layer may be reduced.

Since the adhesion of the two substrates by the glass sealant is weak, and the two substrates might be mechanically separated from each other after being packaged, thus the technical solution of the present embodiment may be applied in the display panel in which the glass sealant is adopted as the sealant for packaging.

### Embodiment 2

The present application provides a display device including the above display panel. The display device may be a LCD panel, a LCD TV, a LCD monitor, a digital photo frame, a mobile phone, a tablet computer, a navigator, an electronic paper or any other product or part with the function of displaying.

### Embodiment 3

The present application provides a method for packaging the display panel, including steps of:

forming the first heat conducting pattern on the first substrate at a position where sealant is to be adhered;

coating the sealant on the first substrate with the sealant in contact with the first heat conducting pattern; and

irradiating the sealant by laser to heat the sealant to melt, and adhering the first substrate and the second substrate by the melted sealant; the first heat conducting pattern conducting heat produced by the laser during the process of irradiating the sealant.

In this embodiment, the first heat conducting pattern is formed on the first substrate at a position corresponding to a position of the sealant layer, and the first heat conducting pattern is in contact with the sealant layer. The first heat conducting pattern is capable of conducting heat produced by the laser during the process of heating the sealant by the laser to form the sealant layer for adhering the first substrate and the second substrate, so that the heat may spread during the process of heating the sealant by the laser, and thus the sealant is heated sufficiently to be melted. As a result, the adhesion of the first substrate and the second substrate by the sealant is enhanced. Furthermore, at least a portion of the sealant is not in direct contact with the first substrate, so that it is solved the problem of the stress caused by mismatching of thermal expansion coefficients of the sealant and the substrates, and thus the adhesion of the first substrate and the second substrate by the sealant is further enhanced, and the mechanical strength of the packaging is improved. Furthermore, before the step of coating the sealant on the first substrate, the method further includes: forming a second heat conducting pattern on the second substrate at a position corresponding to a position where is the sealant is to be adhered. Then, the second heat conducting pattern is in contact with the sealant coated on the first substrate. In the process of irradiating the sealant by laser to heat the sealant to melt so as to adhere the first substrate and the second substrate with the melted sealant, the second heat conducting pattern is capable of conducting heat produced by the laser, so that the heat may spread to each area during the process of heating the sealant by the laser, and thus the sealant in each area is heated sufficiently to be melted. As a result, the adhesion of the first substrate and the second substrate by the sealant is enhanced. Furthermore, at least a portion of the sealant is not in direct contact with the second substrate, so that it is solved the problem of the stress caused by mismatching of thermal expansion coefficients of the sealant and the substrates, and thus the adhesion of the first substrate and the second substrate by the sealant is further enhanced, and the mechanical strength of the packaging is improved.

### Embodiment 4

FIG. 1 illustrates the OLED display device in the related art. As illustrated in FIG. 1, the OLED device includes the packaging substrate 1 and the OLED array substrate which are oppositely arranged to form a cell. The OLED display substrate includes a base substrate 9, an inorganic buffer layer 8, an active layer 2, a first insulation layer 7, a source-drain electrode layer 3, a second insulation layer 6, a pixel electrode 11, an anode layer connected with the pixel electrode 11, a pixel light-emitting area 4 and a cathode layer 13. The OLED array substrate and the packaging substrate 1 are adhered by the glass sealant 5. However, in such arrangement, the adhesion of the two substrates is weak, and thus the two substrates might be mechanically separated from each other after being packaged.

In this embodiment, for solving the above technical problem, it is provided a method for packaging the OLED display panel including following steps.

Step 1: cleaning the packaging substrate 1.

The packaging substrate 1 may be a glass substrate on which no circuit elements have been arranged, or a touch substrate on which circuit elements have been arranged. In particular, the packaging substrate 1 may be placed into a cleaning tank containing cleaning solution or clear water, and cleaned automatically by an air knife and a brush in the cleaning tank. Then, the cleaned packaging substrate 1 may be placed into an oven for drying treatment, so that the moisture on the surface of the packaging substrate 1 is removed.

Step 2: forming the heat conducting pattern 10 on the packaging substrate 1 at a position where the glass sealant is to be adhered.

In particular, an indium tin oxide (ITO) film of a certain thickness may be formed on the packaging substrate 1 by magnetron sputtering process, and an ITO pattern as illustrated in FIG. 4 may be formed by patterning process. The ITO pattern formed on the packaging substrate 1 is in a shape of a frame, and is at a position corresponding to the position of the sealant layer.

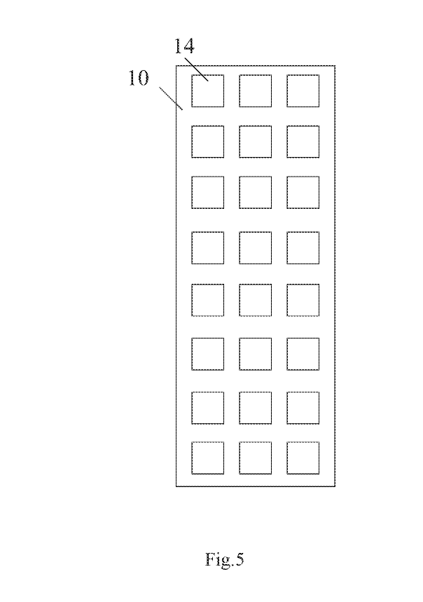

As a matter of fact, the shape of the ITO pattern is not limited to that illustrated in FIG. 3. The ITO pattern may be of any shape such as the rectangular, and may be a full pattern or a pattern with hollow areas. In particular, as illustrated in FIG. 5, the ITO pattern may include a plurality of hollow areas 14 which are in the shape of a square. The presence of hollow areas 14 can increase contact area between the sealant layer and the packaging substrate, and release the stress better upon adhering the packaging substrate and the OLED array substrate by the sealant layer, so that the adhesion of the packaging substrate and the OLED array substrate is further enhanced, and thus the mechanical strength of the packaging is improved. Optionally, when the ITO pattern is a full pattern without any hollow area, the ITO pattern completely covers the orthographic projection of the sealant layer on the packaging substrate.

The material of the heat conducting pattern 10 is not limited to the ITO, and may be any other similar material such as indium zinc oxide (IZO) or indium gallium zinc oxide (IGZO), as long as the material has characteristics of high transmittance, small resistance, good thermostability, and etc.

Step 3: coating or printing the glass sealant 5 on the packaging substrate 1 after the step 2 with the glass sealant 5 being formed into a packaging frame in a predetermined pattern.

Step 4: preprocessing the glass sealant 5 formed on the packaging substrate 1.

In particular, the glass sealant 5 may be pre-dried under a temperature of 150-200° C., and then the packaging substrate 1 is placed into the oven and heated in a stepped high temperature after the pre-drying process to remove all of the organic materials in the packaging substrate 1 under a temperature of 300-350° C.

Step 5: oppositely arranging the packaging substrate 1 which has been preprocessed in the step 4 with respect to the OLED array substrate to form a cell.

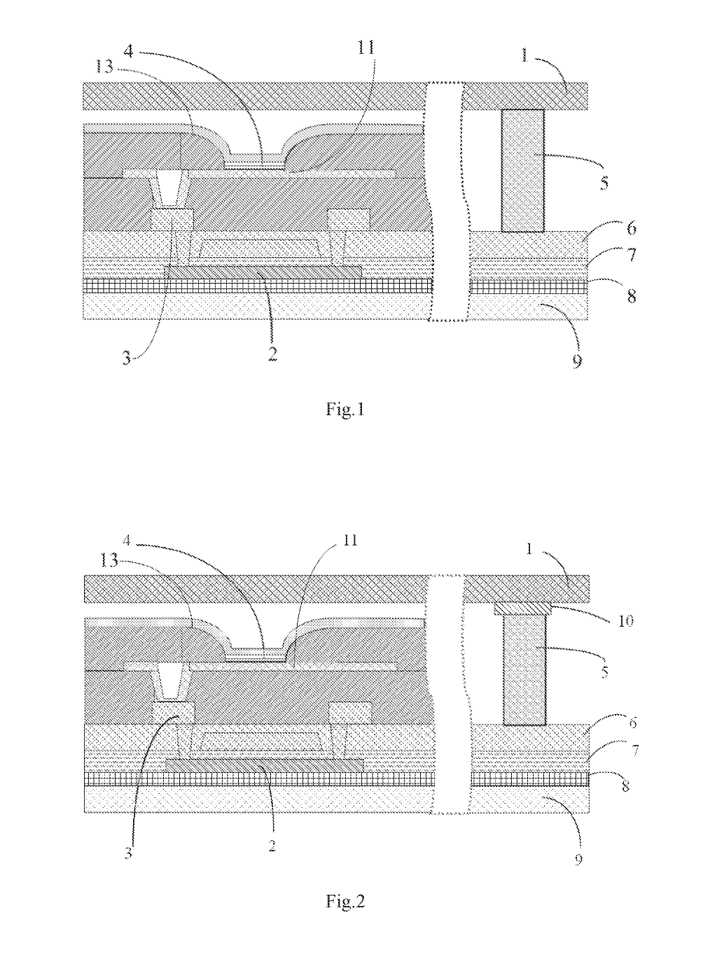

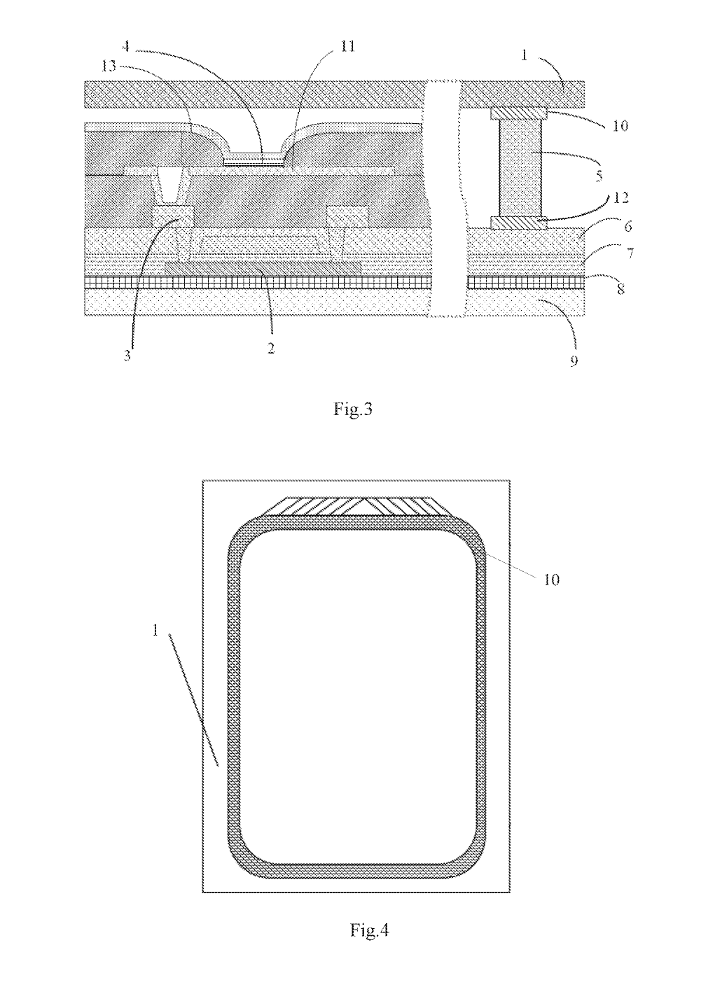

In particular, the packaging substrate 1 and the OLED array substrate are arranged oppositely and laminated by an external force. The glass sealant 5 is irradiated by the laser to be heated and melted, and then is cooled and solidified to form the sealant layer for packaging photoelectric devices therein as illustrated in FIG. 2. Since the organic material is sensitive to the high temperature caused by the irradiation of the laser, it is required that both the organic light-emitting layer and the organic protection layer on the OLED array substrate are kept in a predetermined range of distance from the sealant layer for safety.

Upon heating the glass sealant by the laser, the ITO pattern may conduct the heat generated by the laser to spread the heat, so that the glass sealant is heated sufficiently to melt. As a result, the adhesion of the packaging substrate and the OLED substrate is enhanced. Furthermore, the glass sealant is not in direct contact with the packaging substrate due to the ITO pattern, so that it is solved the problem of the stress caused by mismatching of thermal expansion coefficients of the sealant and the substrates, and thus the adhesion of the packaging substrate and the OLED array substrate by the sealant is further enhanced, and the mechanical strength of the packaging is improved.

Furthermore, since the ITO pattern has electrical conductivity and the cathode layer 13 on the OLED array substrate is a whole layer and near the substrate 1, thus, the ITO pattern may be electrically connected to the cathode layer 13 on the OLED array substrate via two or more connecting points, respectively. As a result, the ITO pattern may be in parallel connection with the cathode layer 13 on the OLED array substrate, and thus the resistance and the voltage drop of the cathode layer 13 may be reduced, and the performance of the OLED display device is improved.

In this embodiment, the method for packaging is explained by an example in which the heat conducting pattern 10 is arranged on the packaging substrate 1, but the present application is not limited to this example. Alternatively, as illustrated in FIG. 3, a heating conducting pattern 12 may also be arranged on the OLED array substrate at a position corresponding to the position of the sealant layer for further improving the packaging strength of the OLED display device.

The above are merely the preferred embodiments of the present application and shall not be used to limit the scope of the present application. It should be noted that, a person skilled in the art may make improvements and modifications without departing from the principle of the present application, and these improvements and modifications shall also fall within the scope of the present application.

1. A display panel, comprising:
a first substrate;
a second substrate which is oppositely arranged with respect to the first substrate to form a cell;
a sealant layer arranged between the first substrate and the second substrate;
wherein the first substrate and the second substrate are adhered together by the sealant layer; and
a first heat conducting pattern arranged on the first substrate at a position corresponding to a position of the sealant layer, and the first heat conducting pattern being in contact with the sealant layer.

2. The display panel according to claim 1, wherein the first heat conducting pattern is a full pattern without any hollow area.

3. The display panel according to claim 2, wherein an orthographic projection of the sealant layer on the first substrate entirely falls into an area corresponding to the first heat conducting pattern.

4. The display panel according to claim 1, wherein the first heat conducting pattern comprises a plurality of hollow areas defined therein.

5. The display panel according to claim 4, wherein each of the hollow areas is in a shape of square, rectangular, triangle or circle.

6. The display panel according to claim 1, further comprising a second heat conducting pattern arranged on the second substrate at a position corresponding to the position of the sealant layer, and the second heat conducting pattern being in contact with the sealant layer.

7. The display panel according to claim 6, wherein the second heat conducting pattern is a full pattern without any hollow area; or
the second heat conducting pattern comprises a plurality of hollow areas defined therein.

8. The display panel according to claim 7, wherein when the second heat conducting patter is the full pattern without any hollow area, an orthographic projection of the sealant layer on the second substrate entirely falls into an area corresponding to the second heat conducting pattern.

9. The display panel according to claim 6, wherein both the first heat conducting pattern and the second heat conducting pattern are made of inorganic electricity conductive material.

10. The display panel according to claim 9, wherein the inorganic electricity conductive material is indium tin oxide (ITO), indium zinc oxide (IZO) or indium gallium zinc oxide (IGZO).

11. The display panel according to claim 9, wherein the first substrate is an array substrate, and the second substrate is a color filter substrate; or, the first substrate is the color filter substrate, and the second substrate is the array substrate.

12. The display panel according to claim 9, wherein the second substrate is an organic light emitting diode (OLED) array substrate, and the first substrate is a packaging substrate.

13. The display panel according to claim 12, wherein the first heat conducting pattern is electrically connected to a cathode layer on the OLED array substrate via two or more connecting points, respectively.

14. The display panel according to claim 1, wherein the sealant layer is made of glass sealant.

15. A display device comprising the display panel according claim 1.

16. A method for packaging the display panel according to claim 1, comprising steps of:
forming the first heat conducting pattern on the first substrate at a position where the sealant is to be adhered;
coating the sealant on the first substrate with the sealant in contact with the first heat conducting pattern; and
irradiating the sealant by laser to heat the sealant to melt, and adhering the first substrate and the second substrate by the melted sealant; wherein the first heat conducting pattern is capable of conducting heat produced by the laser during the process of irradiating the sealant.

17. The method according to claim 16, wherein before the step of coating the sealant on the first substrate, the method further comprises: forming a second heat conducting pattern on the second substrate at a position where the sealant is to be adhered;
wherein the sealant coated on the first substrate is in contact with the second heat conducting pattern; during the process of irradiating the sealant by laser to heat the sealant to melt and adhering the first substrate and the second substrate by the melted sealant, the second heat conducting pattern is capable of conducting heat produced by the laser.

18. A display device comprising the display panel according to claim 2.

19. A display device comprising the display panel according to claim 6.

20. A display device comprising the display panel according to claim 8.
